(19) United States
(12) Patent Application Publication
(10) Pub. No.: US 2023/0002927 A1
(43) Pub. Date: Jan. 5, 2023

(54) LI+ DOPED METAL HALIDE SCINTILLATION CRYSTAL WITH ZERO-DIMENSIONAL PEROVSKITE STRUCTURE, PREPARATION METHOD AND USE THEREOF

(71) Applicant: CHINA JILIANG UNIVERSITY, Zhejiang (CN)

(72) Inventors: Qinhua Wei, Zhejiang (CN); Peng Xiang, Zhejiang (CN); Laishun Qin, Zhejiang (CN)

(21) Appl. No.: 17/732,021

(22) Filed: Apr. 28, 2022

(30) Foreign Application Priority Data
Jul. 1, 2021 (CN) 202110741539.2

(51) Int. Cl. C30B 11/02; C30B 11/00; G01T 3/06

(52) U.S. Cl. CPC C30B 11/02; C30B 11/003; G01T 3/06

(57) ABSTRACT

Disclosed are a Li⁺ doped metal halide scintillation crystal with a zero-dimensional perovskite structure, a preparation method and use thereof. The scintillation crystal has a chemical formula of Cs₃₋ₓCu₂I₅:xLi, where x is in a range of 0.003 to 0.3. The method for preparing the scintillation crystal comprises the steps of: weighting and fully mixing a CuI powder, a CsI powder and a LiI powder in a molar ratio of 2:(3-x):x in an inert atmosphere to obtain a mixed powder, and growing into the scintillation crystal from the mixed powder by Bridgman Stockbarger method. After excited, the scintillation crystal could emit a broadband blue light in a range of 350-550 nm, with an intensity much higher than that of the original pure component crystal. The existence of Li⁺ further expands the application of the scintillation crystals from X/γ-ray detection to neutron detection.

### TECHNICAL FIELD

The present disclosure relates to the technical field of artificial scintillation crystals, in particular to a Li⁺ doped metal halide scintillation crystal with a zero-dimensional perovskite structure, a preparation method and use thereof.

### BACKGROUND ART

Scintillators are a kind of materials that can emit light after absorbing high-energy rays or particles, among which, scintillation crystals have the best comprehensive performance. As a key core material of radiation detectors, scintillation crystals have been widely used in the fields of medical imaging, homeland security, high-energy physics, etc. In order to meet the requirements on sensitivity and confidence coefficient of high-performance energy spectroscopies and imaging detectors, the development of new scintillation crystal materials with high light output and high energy resolution has always been a frontier research direction in the field of radiation detection. Lead-halide perovskites have attracted much attention due to their high ray absorption coefficient, low density of defect states, continuously tunable band gap, and large carrier mobility/lifetime product. However, the toxicity and bioconcentration of lead cannot be ignored, and lead-halide perovskites are often unstable and self-absorbed. In recent years, there have been metal halide materials with a low-dimensional perovskite structure, which are considered as a potential high-performance scintillation material with the advantages such as no self-absorption and high luminous efficiency due to the characteristics such as confined exciton emission, large Stokes shift and high fluorescence quantum efficiency. Recently, related research based on Cu(I) system has progressed rapidly. Typically, the 1D perovskite-structured Rb₂CuBr₃ has a scintillation yield of over 90,000 ph/MeV under X-ray radiation, which is comparable to cutting-edge commercial scintillators, but the presence of Rb⁺ leads to introduce an unnecessary radioactive background in the scintillator. By comparison, Cs₃Cu₂I₅, which uses Cs+ without natural radioactivity instead of Rb⁺ and has a lower zero-dimensional structure and also emits light from self-trapped excitons (STE), has more practical application prospects.

A single crystal of Cs₃Cu₂I₅ has a Stokes shift of about 150 nm, which avoids self-absorption loss; a center of emission peak of near 445 nm, which is suitable for commercial photomultiplier tubes and is conducive to device integration; an effective atomic number as high as 52.2, and a density of about 4.5 g/cm³, corresponding to a large ray absorption coefficient; an afterglow signal which drops by 4 orders of magnitude within 10 ms after the X-ray cut-off, which is much better than the commercial CsI:Tl; an X-ray detection limit of about 100 nGyair/s, which is dozens of times lower than the medical diagnosis requirements; a main decay time under 137Cs γ-ray radiation of about 1 μs, which is much shorter than other low-dimensional perovskites; and an energy resolution at 662 keV as high as 3.4% due to the low nonproportionality in the radiation energy range. Moreover, by incorporating a suitable concentration of Tl⁺, the photoluminescence efficiency (PLQY) of the original pure component, which is close to 70%, is further improved by nearly 10%; the steady-state scintillation yield under X-ray excitation is increased from 32,000 ph/MeV to 150,000 ph/MeV, close to the theoretical limit; the absolute light yield at 662 keV is 87,000 ph/MeV, which is comparable to state-of-the-art γ-ray detectors such as LaBr₃:Ce, Sr and SrI₂:Eu. Although the introduction of Tl⁺ results in greatly improved scintillation performance of Cs₃Cu₂I₅ single crystals, it brings considerable safety hazards due to the highly toxic nature of thallium itself. Therefore, it is urgent to find a metal-doped ion that could meet the requirements of high light output without harming environment and health.

### SUMMARY

In view of the above, an object of the present disclosure is to provide a Li⁺ doped metal halide scintillation crystal with a zero-dimensional perovskite structure and a preparation method thereof. The incorporation of Li makes it possible not only to improve the light output performance of the original pure component crystal, but also to further extend the use of the original pure component crystal to neutron detection. In order to achieve the above and other related objects, the present disclosure first provides a Li⁺ doped metal halide scintillation crystal with a zero-dimensional perovskite structure, having a chemical formula of Cs₃₋ₓCu₂I₅:xLi, wherein x is in a range of 0.003 to 0.3.

When excited by a 300 nm light source, the Li⁺ doped metal halide scintillation crystal with a zero-dimensional perovskite structure has an emission wavelength of 350-550 nm; compared with the pure component crystal, it has no obvious shift, but exhibits a greatly improved fluorescence intensity.

The present disclosure also provides a method for preparing the Li⁺ doped metal halide scintillation crystal with a zero-dimensional perovskite structure as described in the above technical solutions, comprising the steps of: weighting and fully mixing a CuI powder, a CsI powder and a LiI powder in a molar ratio of 2:(3-x):x in an inert atmosphere to obtain a mixed powder, wherein x is in a range of 0.003 to 0.3; adding the mixed powder to a spontaneous nucleation quartz crucible, and then sealing the crucible under vacuum; and growing into the Li⁺ doped metal halide scintillation crystal with a zero-dimensional perovskite structure having a chemical formula of Cs₃₋ₓCu₂I₅:xLi from the mixed powder by Bridgman Stockbarger method.

Another aspect of the present disclosure provides use of the Li⁺ doped metal halide scintillation crystal with a zero-dimensional perovskite structure as described in the above technical solutions in the detection of rays and neutron.

### BRIEF DESCRIPTION OF THE DRAWINGS

FIG. 1 shows photographs of real objects of the LF doped metal halide scintillation crystals with a zero-dimensional perovskite structure according to Examples 1-5.

FIG. 2 shows the X-ray diffraction pattern of Cs_{2.85}Cu₂I₅:5% Li scintillation crystal according to Example 1.

FIG. 3 shows the fluorescence spectra of Cs_{2.85}Cu₂I₅:5% Li scintillation crystal according to Example 1, Cs_{2.997}Cu₂I₅:0.1% Li scintillation crystal according to Example 2, Cs_{2.91} Cu₂I₅:3% Li scintillation crystal according to Example 4, and Cs_{2.7} Cu₂I₅:10% Li scintillation crystal according to Example 5.

FIG. 4 shows the X-ray excitation emission spectra of Cs_{2.85} Cu₂I₅:5% Li scintillation crystal according to Example 1, Cs_{2.997}Cu₂I₅:0.1% Li scintillation crystal according to Example 2, Cs_{2.97} Cu₂I₅:1% Li scintillation crystal according to Example 3, and Cs_{2.7} Cu₂I₅:10% Li scintillation crystal according to Example 5.

FIG. 5 shows the decay time of the Cs_{2.85} Cu₂I₅:5% Li scintillation crystal according to Example 1.

FIG. 6 is a diagram showing transmittance of the Cs_{2.85} Cu₂I₅:5% Li scintillation crystal according to Example 1 and the Cs_{2.997}Cu₂I₅:0.1% Li scintillation crystal according to Example 2.

### DETAILED DESCRIPTION OF THE EMBODIMENTS

The present disclosure will be further described below in conjunction with the drawings and examples. It should be understood that the drawings and examples are only intended to illustrate, not to limit the present disclosure.

In the present disclosure, a new scintillation crystal material that meets the use requirements of high-performance energy spectroscopies and imaging detectors is developed by studying the Cs₃₋ₓCu₂I₅:xLi metal halide scintillation crystal with a zero-dimensional perovskite structure. In the present disclosure, Cs₃₋ₓCu₂I₅:xLi metal halide scintillation crystal with a zero-dimensional perovskite structure is prepared using the CsI powder, the CuI powder and the LiI powder as raw materials, wherein x is in a range of larger than 0.003 to less than or equal to 0.3, based on the characteristic found in practice that Li⁺ could improve luminous intensity without changing the ranges of excitation light and emission light of the original pure component crystal.

Preparation:

Crucible cleaning: the quartz crucible is ultrasonically cleaned with a low-concentration nitric acid, deionized water and an alcohol in sequence with a liquid level of slightly higher than the main diameter of the crucible, for 20-30 min each time. After cleaning, the crucible is wiped to remove water on the surface thereof, dried in a drying oven overnight, and then placed in a glove box for 2-3 days in advance to ensure that the inner wall of the crucible is free of water when being charged.

Batching of raw materials: in a glove box with an inert atmosphere, the CuI powder, the CsI powder and the LiI powder are weighted based on a molar ratio of 2:(3-x):x, wherein x is in a range of 0.003 to 0.3, and fully mixed to obtain a mixed powder; then the mixed powder is added to a spontaneous nucleation quartz crucible, and the crucible is sealed under vacuum. In some embodiments, the mixed powder has a high purity, for example, a purity of 99.99% or more, preferably 99.999% or more.

Crystal growth: the crystal is grown by the Bridgman Stockbarger method under conditions of a vacuum environment, a growth rate controlled at 0.2-1 mm/h, and a temperature in the high temperature zone of a growth furnace of 470-550° C. with a gradient of 15-35° C./mm.

The present disclosure is further illustrated by the following examples. It should be understood that the following examples are only used to better illustrate the present disclosure, and should not be construed as limiting the protection scope of the present disclosure. Similar adjustments and optimizations made by those skilled in the art according to the above contents of the present disclosure are all within the protection scope of the present disclosure. The experimental methods that do not specify conditions in the following examples are generally performed in accordance with conventional conditions.

Example 1: Spontaneous nucleation growth of Cs_{2.85} Cu₂I₅:5% Li scintillation crystal was performed by Bridgman Stockbarger method:

(1) In a glove box with an inert atmosphere, 6.4753 g of CuI powder, 12.5878 g of CsI powder and 0.3413 g of LiI powder were weighted based on a stoichiometric ratio of CuI:CsI:LiI of 2:2.85:0.15, and mixed uniformly, obtaining a mixed powder, wherein the CuI powder, the CsI powder and the LiI powder have a purity of 99.99%/a.

(2) The mixed powder was added to a quartz crucible. After vacuumized, the crucible was sealed by using a flame of a hydrogen-oxygen flame gun to make the quartz column located at the convex part of the narrow wall of the crucible mouth melt with the inner wall, and then placed in a ceramic down pipe. The down pipe was placed on a down mechanism, and the bottom of the crucible was raised to the upper edge of the temperature gradient zone in a descending furnace, and then the temperature was increased.

(3) The temperature of the high temperature zone of the descending furnace was set to be 470° C., and the mixed powder was heated to a molten state and kept for 30 h.

(4) The quartz crucible was lowered at a speed of 0.4 mm/h through the down mechanism.

(5) After the crucible was lowered to a preset distance, the temperature was decreased slowly to room temperature, and then the crucible was taken out and transferred to a glove box. The crystal was taken out by breaking the crucible, cut, ground and polished to be processed into a wafer sample, and the remaining transparent scraps were taken and ground to be processed into a powder sample.

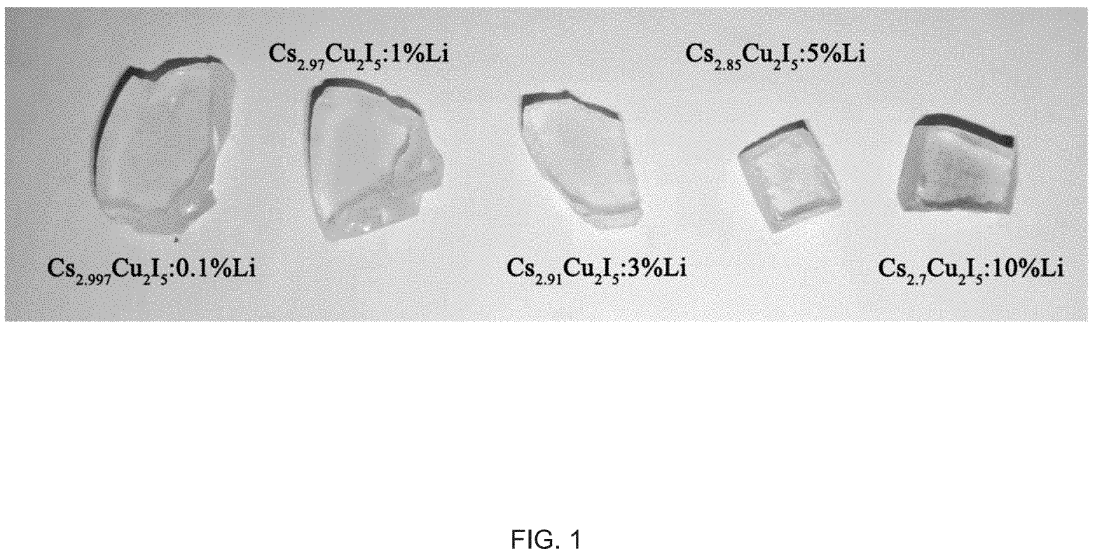

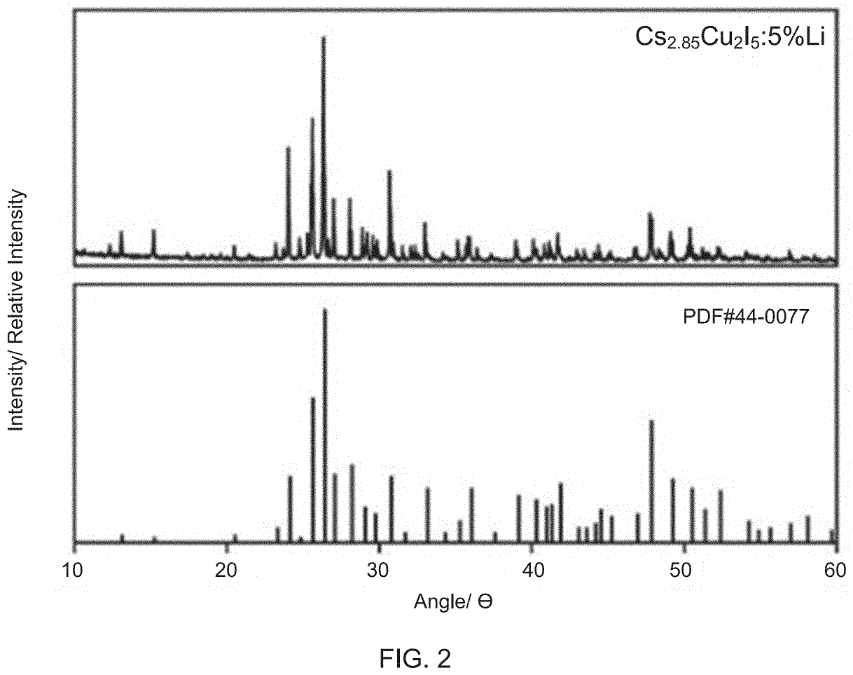

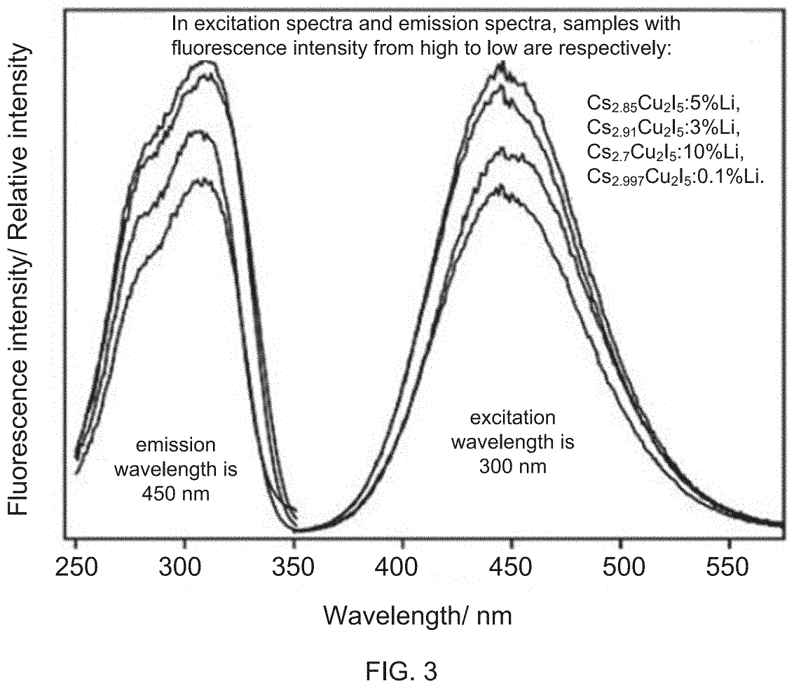

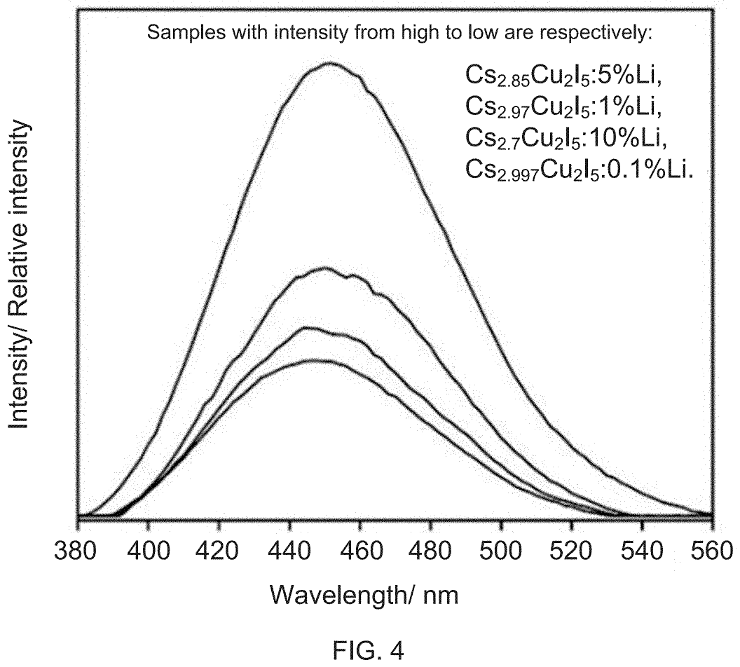

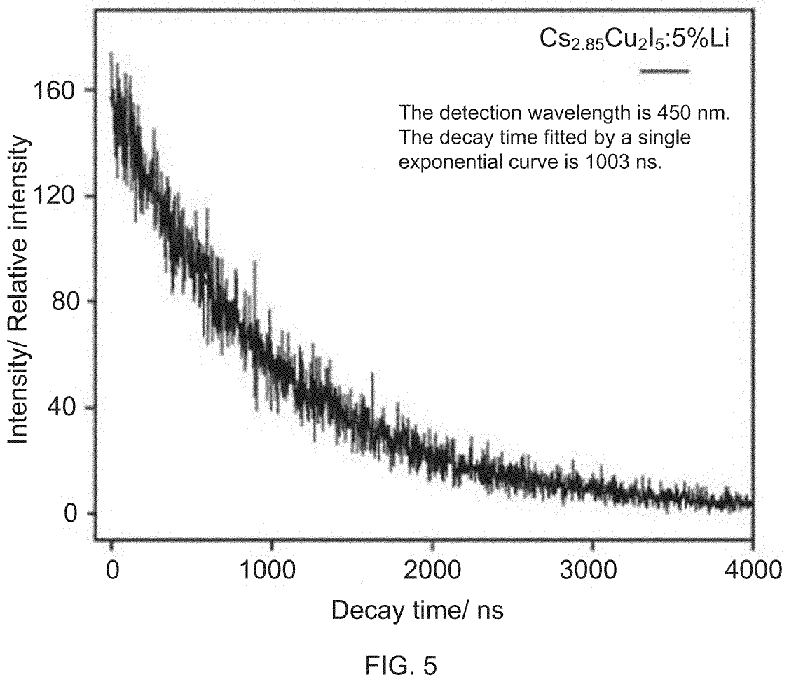

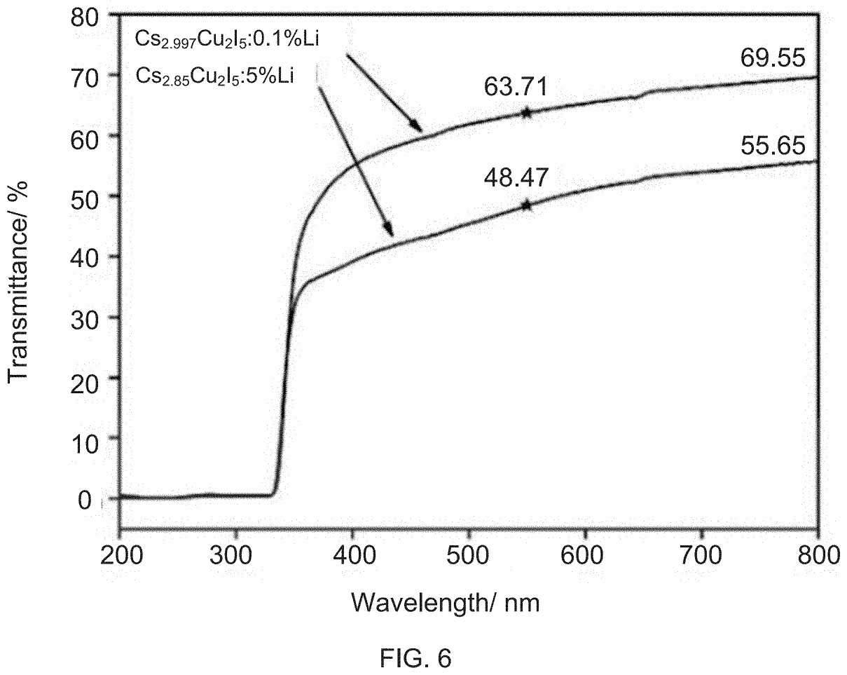

The obtained crystals are of good quality (see FIG. 1). The X-ray diffraction pattern of the powder sample is closely matched with the standard PDF #44-0077 card for Cs₃Cu₂Is with a good crystallinity (see FIG. 2). When the sample is excited by a 300 nm light source, the self-trapped excitons with an emission center at 446 nm and a range of 350-550 nm are shown to emit light, with a greatly improved emission intensity compared to the pure component crystal (see FIG. 3). The emission spectra under X-ray excitation shows similar results to the fluorescence spectra, indicating an absence of obvious structural defects in the crystals (see FIG. 4). The normal temperature decay time at the monitoring wavelength of 450 nm is 1003 ns (see FIG. 5), which meets the needs of practical radiation detection applications. The wafer sample maintains a good transmittance within the emission band, which is convenient for a photon detector to receive the optical signal (see FIG. 6).

Example 2: Spontaneous nucleation growth of Cs_{2.997}Cu₂I₅:0.1% Li scintillation

crystal was performed by Bridgman Stockbarger method:

(1) In a glove box with an inert atmosphere, 6.4753 g of CuI powder, 13.2371 g of CsI powder and 0.0068 g of LiI powder were weighted based on a stoichiometric ratio of CuI:CsI:LiI of 2; 2.85; 0.15, and mixed uniformly, obtaining a mixed powder, wherein the CuI powder, the CsI powder and the LiI powder have a purity of 99.99%.

(2) The mixed powder was added to a spontaneous nucleation quartz crucible. After vacuumized, the crucible was sealed by using a flame of a hydrogen-oxygen flame gun to make the quartz column located at the convex part of the narrow wall of the crucible mouth melt with the inner wall, and then placed in a ceramic down pipe. The down pipe was placed on a down mechanism, and the bottom of the crucible was raised to the upper edge of the temperature gradient zone in a descending furnace, and then the temperature was increased.

(3) The temperature of the high temperature zone of a descending furnace was set to be 490° C., and the mixed powder was heated to a molten state and kept for 30 h.

(4) The quartz crucible was lowered at a speed of 1 mm/h through the down mechanism.

(5) After the crucible was lowered to a preset distance, the temperature was decreased slowly to room temperature, and then the crucible was taken out and transferred to a glove box. The crystal was taken out by breaking the crucible, cut, ground and polished to be processed into a wafer sample, and the remaining transparent scraps were taken and ground to be processed into a powder sample.

The obtained crystals are of good quality (see FIG. 1). When the sample is excited by a 300 nm light source, the self-trapped excitons with an emission center at 446 nm and a range of 350-550 nm are shown to emit light (see FIG. 3). The emission spectra under X-ray excitation shows similar results to the fluorescence spectra, indicating an absence of obvious structural defects in the crystals (see FIG. 4). The wafer sample maintains a good transmittance within the emission band, which is convenient for a photon detector to receive the optical signal (see FIG. 6).

Example 3: Spontaneous nucleation growth of Cs_{2.97}Cu₂I₅:1% Li scintillation crystal was performed by Bridgman Stockbarger method;

(1) In a glove box with an inert atmosphere, 6.4753 g of CuI powder, 13.1178 g of CsI powder and 0.0683 g of LiI powder were weighted based on a stoichiometric ratio of CuI:CsI:LiI of 2:2.85:0.15, and mixed uniformly, obtaining a mixed powder, wherein the CuI powder, the CsI powder and the LiI powder have a purity of 99.99%.

(2) The mixed powder was added to a spontaneous nucleation quartz crucible. After vacuumized, the crucible was sealed by using a flame of a hydrogen-oxygen flame gun to make the quartz column located at the convex part of the narrow wall of the crucible mouth melt with the inner wall, and then placed in a ceramic down pipe. The down pipe was placed on a down mechanism, and the bottom of the crucible was raised to the upper edge of the temperature gradient zone in a descending furnace, and then the temperature was increased.

(3) The temperature of the high temperature zone of the descending furnace was set to be 510° C., and the mixed powder was heated to a molten state and kept for 30 h.

(4) The quartz crucible was lowered at a speed of 0.8 mm/h through the down mechanism.

(5) After the crucible was lowered to a preset distance, the temperature was decreased slowly to room temperature, and then the crucible was taken out and transferred to a glove box. The crystal was taken out by breaking the crucible, cut, ground and polished to be processed into a wafer sample, and the remaining transparent scraps were taken and ground to be processed into a powder sample.

The obtained crystals are of good quality (see FIG. 1). When the sample is excited by a 300 nm light source, the self-trapped excitons with an emission center at 446 nm and a range of 350-550 nm are shown to emit light, with a greatly improved emission intensity compared to the pure component crystal (see FIG. 3). The emission spectra under X-ray excitation shows similar results to the fluorescence spectra, indicating an absence of obvious structural defects in the crystals (see FIG. 4).

Example 4: Spontaneous nucleation growth of Cs_{2.91} Cu₂I₅:3% Li scintillation crystal was performed by Bridgman Stockbarger method:

(1) In a glove box with an inert atmosphere, 6.4753 g of CuI powder, 12.8528 g of CsI powder and 0.2048 g of LiI powder were weighted based on a stoichiometric ratio of CuI:CsI:LiI of 2:2.85:0.15, and mixed uniformly, obtaining a mixed powder, wherein the CuI powder, the CsI powder and the LiI powder have a purity of 99.99%.

(2) The mixed powder was added to a spontaneous nucleation quartz crucible. After vacuumized, the crucible was sealed by using a flame of a hydrogen-oxygen flame gun to make the quartz column located at the convex part of the narrow wall of the crucible mouth melt with the inner wall, then placed in a ceramic down pipe. The down pipe was placed on a down mechanism, and the bottom of the crucible was raised to the upper edge of the temperature gradient zone in a descending furnace, and then the temperature was increased.

(3) The temperature of the high temperature zone of the descending furnace was set to be 530° C., and the mixed powder was heated to a molten state and kept for 30 h.

(4) The quartz crucible was lowered at a speed of 0.6 mm/h through the down mechanism.

(5) After the crucible was lowered to a preset distance, the temperature was decreased slowly to room temperature, and then the crucible was taken out and transferred to a glove box. The crystal was taken out by breaking the crucible, cut, ground and polished to be processed into a wafer sample, and the remaining transparent scraps were taken and ground to be processed into a powder sample.

The obtained crystals are of good quality (see FIG. 1). When the sample is excited by a 300 nm light source, the self-trapped excitons with an emission center at 446 nm and a range of 350-550 nm are shown to emit light, with a greatly improved emission intensity compared to the pure component crystal (see FIG. 3). The emission spectra under X-ray excitation shows similar results to the fluorescence spectra, indicating an absence of obvious structural defects in the crystals (see FIG. 4).

Example 5: Spontaneous nucleation growth of Cs_{2.7} Cu₂I₅:10% Li scintillation crystal was performed by Bridgman Stockbarger method:

(1) In a glove box with an inert atmosphere, 6.4753 g of CuI powder, 11.9253 g of CsI powder and 0.6826 g of LiI powder were weighted based on a stoichiometric ratio of CuI:CsI:LiI of 2:2.85:0.15, and mixed uniformly, obtaining a mixed powder, wherein the CuI powder, the CsI powder and the LiI powder have a purity of 99.99%.

(2) The mixed powder was added to a spontaneous nucleation quartz crucible. After vacuumized, the crucible was sealed by using a flame of a hydrogen-oxygen flame gun to make the quartz column located at the convex part of the narrow wall of the crucible mouth melt with the inner wall, then placed in a ceramic down pipe. The down pipe was placed on a down mechanism, and the bottom of the crucible was raised to the upper edge of the temperature gradient zone in a descending furnace, and then the temperature was increased.

(3) The temperature of the high temperature zone of the descending furnace was set to be 550° C., and the mixed powder was heated to a molten state, and kept for 30 h.

(4) The quartz crucible was lowered at a speed of 0.2 mm/h through the down mechanism.

(5) After the crucible was lowered to a preset distance, the temperature was decreased slowly to room temperature, and then the crucible was taken out and transferred to a glove box. The crystal was taken out by breaking the crucible, cut, ground and polished to be processed into a wafer sample, and the remaining transparent scraps were taken and ground to be processed into a powder sample.

The obtained crystals are of good quality (see FIG. 1). When the sample is excited by a 300 nm light source, the self-trapped excitons with an emission center at 446 nm and a range of 350-550 nm are shown to emit light (see FIG. 3). The emission spectra under X-ray excitation shows similar results to the fluorescence spectra, indicating an absence of obvious structural defects in the crystals (see FIG. 4).

What is claimed is:

1. A Li⁺ doped metal halide scintillation crystal with a zero-dimensional perovskite structure, which has a chemical formula of Cs₃₋ₓCu₂I₅:xLi.

2. The Li⁺ doped metal halide scintillation crystal with a zero-dimensional perovskite structure of claim 1, wherein x is in a range of 0.003 to 0.3.

3. The Li⁺ doped metal halide scintillation crystal with a zero-dimensional perovskite structure of claim 1, wherein the scintillation crystal emits a broadband blue light in a range of 350-550 nm when excited by high-energy rays or high-energy particles.

4. The Li⁺ doped metal halide scintillation crystal with a zero-dimensional perovskite structure of claim 1, wherein the scintillation crystal identifies neutrons and γ-rays under a co-irradiation of neutrons and γ-rays.

5. A method for preparing a Li⁺ doped metal halide scintillation crystal with a zero-dimensional perovskite structure, comprising the steps of:
mixing a CuI powder, a CsI powder and a LiI powder in an inert atmosphere to obtain a mixed powder, and
adding the mixed powder to a spontaneous nucleation quartz crucible, then sealing the crucible under vacuum, heating and melting the mixed powder, and growing the mixed powder into the scintillation crystal;
wherein the scintillation crystal has a chemical formula of Cs₃₋ₓCu₂I₅:xLi.

6. The method of claim 5, wherein the CuI powder, the CsI powder and the LiI powder are weighted in a molar ratio of 2:(3-x):x, and fully mixed to obtain the mixed powder, wherein x is in a range of 0.003 to 0.3; and the scintillation crystal is grown from the mixed powder by Bridgman Stockbarger method.

7. A method of using the Li⁺ doped metal halide scintillation crystal with a zero-dimensional perovskite structure of claim 1, comprising using the Li⁺ doped metal halide scintillation crystal in the detection of X-ray, γ-ray or neutron.

8. The Li⁺ doped metal halide scintillation crystal with a zero-dimensional perovskite structure of claim 2, wherein the scintillation crystal emits a broadband blue light in a range of 350-550 nm when excited by high-energy rays or high-energy particles.

9. The Li⁺ doped metal halide scintillation crystal with a zero-dimensional perovskite structure of claim 2, wherein the scintillation crystal identifies neutron and γ-ray under a co-irradiation of neutron and γ-ray.

10. The Li⁺ doped metal halide scintillation crystal with a zero-dimensional perovskite structure of claim 3, wherein the scintillation crystal identifies neutron and γ-ray under a co-irradiation of neutron and γ-ray.

11. The method of claim 5, wherein x is in a range of 0.003 to 0.3.

12. The method of claim 5, wherein the scintillation crystal emits a broadband blue light in a range of 350-550 nm when excited by high-energy rays or high-energy particles.

13. The method of claim 11, wherein the scintillation crystal emits a broadband blue light in a range of 350-550 nm when excited by high-energy rays or high-energy particles.

14. The method of claim 5, wherein the scintillation crystal identifies neutron and γ-ray under a co-irradiation of neutron and γ-ray.

15. The method of claim 11, wherein the scintillation crystal identifies neutron and γ-ray under a co-irradiation of neutron and γ-ray.

16. The method of claim 12, wherein the scintillation crystal identifies neutron and γ-ray under a co-irradiation of neutron and γ-ray.

17. The method of claim 11, wherein the CuI powder, the CsI powder and the LiI powder are weighted in a molar ratio of 2:(3-x):x, and fully mixed to obtain the mixed powder, wherein x is in a range of 0.003 to 0.3; and the scintillation crystal is grown from the mixed powder by Bridgman Stockbarger method.

18. The method of claim 12, wherein the CuI powder, the CsI powder and the LiI powder are weighted in a molar ratio of 2:(3-x):x, and fully mixed to obtain the mixed powder, wherein x is in a range of 0.003 to 0.3; and the scintillation crystal is grown from the mixed powder by Bridgman Stockbarger method.

19. The method of claim 14, wherein the CuI powder, the CsI powder and the LiI powder are weighted in a molar ratio of 2:(3-x):x, and fully mixed to obtain the mixed powder, wherein x is in a range of 0.003 to 0.3; and the scintillation crystal is grown from the mixed powder by Bridgman Stockbarger method.

20. A method of using the Li⁺ doped metal halide scintillation crystal with a zero-dimensional perovskite structure of claim 2, comprising using the Li⁺ doped metal halide scintillation crystal in the detection of X-ray, γ-ray or neutron.
